(19) United States
(12) Patent Application Publication
(10) Pub. No.: US 2025/0026917 A1
(43) Pub. Date: Jan. 23, 2025

(54) ULTRAVIOLET-CURABLE RESIN COMPOSITION, ADHESIVE, SEALANT, INSULATING PROTECTIVE AGENT, AND ELECTRONIC CIRCUIT BOARD

(71) Applicant: PELNOX, LTD., Kanagawa (JP)

(72) Inventors: Kazuki KIMURA, Osaka (JP); Toshihiro YASUNAGA, Kanagawa (JP)

(21) Appl. No.: 18/689,648

(22) PCT Filed: Sep. 5, 2022
(86) PCT No.: PCT/JP2022/033250

§ 371 Date: Sep. 30, 2024

(30) Foreign Application Priority Data
Sep. 10, 2021 (JP) 2021-147511

(51) Int. Cl. C08K 5/45; C08F 2/44; C08F 2/50; C08F 222/10; C08K 5/24; C08K 5/5397; C09J 135/02; C09K 3/10; H05K 1/02

(52) U.S. Cl. CPC C08K 5/45; C08F 2/44; C08F 2/50; C08F 222/103; C08K 5/24; C08K 5/5397; C09J 135/02; C09K 3/10; H05K 1/0256; C09K 2003/1062; H05K 2201/0112; H05K 2201/0179

(57) ABSTRACT

One ultraviolet-curable resin composition of the present invention includes: (A) at least one polymer selected from the group consisting of poly(meth)acrylates (a1) and polyvinyl ethers (a2); (B) a compound having at least two secondary thiol groups in a molecule thereof; (C) a photopolymerization initiator a solution of which in acetonitrile with a concentration of 500 ppm has an absorbance of 0.50 or more in an optical path length of 10 mm at 385 nm; and (D) an organic compound that emits light upon absorbing ultraviolet rays, having a maximum wavelength of an absorption spectrum in a range of 300 nm or more and 450 nm or less, and having a maximum wavelength of an emission spectrum in a range of 350 nm or more and 500 nm or less; wherein a content of the compound (B) is 10 mass % or more and 70 mass % or less based on 100 mass % of the resin composition in terms of solid content.

### TECHNICAL FIELD

The present invention relates to an ultraviolet-curable resin composition, an adhesive, a sealant, an insulating protective agent, and an electronic circuit board.

### BACKGROUND ART

Ultraviolet-curable resin compositions are commonly cured via a process in which on being irradiated with ultraviolet rays, photopolymerization initiators generate active radicals, acids, or the like, and polymerizable compounds such as (meth)acrylates, epoxy compounds, or the like are polymerized. However, in an environment where an ultraviolet-curable resin composition is used, if there is a portion to which light does not reach (light shielding portion), such as a shadow portion or a narrow portion, ultraviolet rays cannot sufficiently reach a portion shielded by the light shielding portion, and thus there is a problem that curing of the ultraviolet-curable resin composition proceeds insufficiently. In addition, when a thick coating film or a deep molded article is obtained from an ultraviolet-curable resin composition, ultraviolet rays cannot sufficiently reach a deep part of the cured product, so that there is also a problem that curing in the deep part proceeds insufficiently.

As a method for curing such a light shielding portion and a deep portion, there is a method using not only ultraviolet curing but also curing by heat or moisture in combination for commercially available ultraviolet curable resins. However, these curable resins are not necessarily satisfactory because of problems such as deformation and reduction in adhesion due to heat, and the fact that moisture curing takes time.

As another method for curing a light shielding portion, it has been studied to add a material that emits light having a wavelength at which the curing reaction is made to proceed into an ultraviolet-curable resin composition (Patent Documents 1 and 2). However, in the methods of Patent Documents 1 and 2, the distance at which curing of the light shielding portion has been confirmed is about 1 mm or less, and it has been difficult to cure the light shielding portion to a practical level only by ultraviolet irradiation.

### PRIOR ART DOCUMENTS

### Patent Documents

Patent Document 1: WO 2013/105162 A

Patent Document 2: JP 2007-156184 A

### SUMMARY OF THE INVENTION

### Problems to be Solved by the Invention

A problem to be solved by the present invention is to provide a novel ultraviolet-curable resin composition that can be sufficiently cured even in a light shielding portion or a deep portion when cured by irradiation with ultraviolet rays.

### Solutions to the Problems

As a result of intensive studies, the present inventors have found that a composition containing at least one polymer selected from the group consisting of poly(meth)acrylates and polyvinyl ethers, a compound having a prescribed thiol group, a prescribed photopolymerization initiator, and an organic compound that emits light by absorbing prescribed ultraviolet rays can contribute to the solution of the above-described problem. As a result of further research and analysis, the present inventors have found that the above-described problem can be solved with high certainty by the composition containing a specific amount of the above-described compound having a thiol group, and the present invention has been accomplished.

One ultraviolet-curable resin composition of the present invention comprises:
(A) at least one polymer selected from the group consisting of poly(meth)acrylates (a1) and polyvinyl ethers (a2);
(B) a compound having at least two secondary thiol groups in a molecule thereof;
(C) a photopolymerization initiator a solution of which in acetonitrile with a concentration of 500 ppm has an absorbance of 0.50 or more in an optical path length of 10 mm at 385 nm; and
(D) an organic compound that emits light upon absorbing ultraviolet rays, having a maximum wavelength of an absorption spectrum in a range of 300 nm or more and 450 nm or less, and having a maximum wavelength of an emission spectrum in a range of 350 nm or more and 500 nm or less;
wherein a content of the compound (B) is 10 mass % or more and 70 mass % or less based on 100 mass % of the resin composition in terms of solid content.

In addition, in the above-described invention, in one more preferred invention, the component (B) is a compound having at least three secondary thiol groups in a molecule thereof.

In addition, in each of the above-described inventions, in one more preferred invention, the content of the component (D) is 0.00001 mass % or more and 0.05 mass % or less based on 100 mass % of the resin composition in terms of solid content.

In addition, in each of the above-described inventions, in one more preferred invention, the component (D) is at least one compound selected from the group consisting of benzoxazole compounds, naphthalene compounds, anthracene compounds, pyrene compounds, stilbene compounds, and coumarin compounds.

In addition, in each of the above-described inventions, in one more preferred invention, the component (C) is an acylphosphine oxide compound.

In addition, in each of the above-described inventions, one more preferred invention further comprises a polymerization inhibitor (E).

In addition, in each of the above-described inventions, in one more preferred invention, the component (E) is at least one compound selected from the group consisting of aluminum N-nitrosophenylhydroxylamine and phenothiazine.

In addition, in each of the above-described inventions, one application example of a more preferable invention is an adhesive comprising the ultraviolet-curable resin composition of each of the above-described inventions.

In addition, in each of the above-described inventions, one application example of a more preferable invention is a sealant comprising the ultraviolet-curable resin composition of each of the above-described inventions.

In addition, in each of the above-described inventions, one application example of a more preferable invention is an insulating protective agent comprising the ultraviolet-curable resin composition of each of the above-described inventions. In addition, in each of the above-described inventions, one application example of a more preferable invention is an electronic circuit board comprising the insulating protective agent of each of the above-described inventions.

### Effects of the Invention

One ultraviolet-curable resin composition of the present invention can be sufficiently cured at the time of curing by ultraviolet irradiation even when a light shielding portion is present. One ultraviolet-curable resin composition of the present invention can be sufficiently cured even at a deep portion of a cured product such as a thick coating film or a deep molded product. Furthermore, one ultraviolet-curable resin composition of the present invention is superior in curability in a light shielding portion and a deep portion even when cured using ultraviolet rays emitted from a UV-LED light source.

One ultraviolet-curable resin composition of the present invention is superior in curability in a light shielding portion and a deep portion, and thus is suitable as an adhesive to be used for a shadow portion and a narrow portion, for example, an adhesive to be used between a protective panel and a touch panel of an image display device or the like, or an adhesive to be used for bonding various electronic components in an electronic circuit board.

One ultraviolet-curable resin composition of the present invention is superior in curability in a light shielding portion and a deep portion, and thus is suitable as a sealant to be used for a component having a complicated shape and hardly irradiated with ultraviolet rays, a sealant having a shielding portion in a use environment, for example, a sealant to be used for an optical lens unit, a sealant for an electronic component with a lead, and an underfill agent.

One ultraviolet-curable resin composition of the present invention is superior in curability in a light shielding part and a deep part, and thus is suitable as an insulating protective agent to be used for an electronic circuit board with an electronic component mounted thereon.

### BRIEF DESCRIPTION OF THE DRAWINGS

FIG. 1 is a schematic view of a scene where a spacer is disposed on an FRP substrate in evaluation of shadow part curability in Examples.

FIG. 2 is a schematic view of a scene where an ultraviolet-curable resin composition is applied to a portion not covered with a spacer in evaluation of shadow part curability in Examples.

FIG. 3 is a schematic view of a scene where a PET film is bonded in evaluation of shadow part curability in Examples.

FIG. 4 is a schematic view of a scene where a light shielding plate is placed in evaluation of shadow part curability in Examples.

FIG. 5 is a schematic view of a scene where a light shielding plate and a PET film are peeled off after ultraviolet irradiation in evaluation of shadow part curability of Examples.

FIG. 6 is a schematic cross-sectional view of a scene of ultraviolet irradiation in evaluation of shadow part curability of Examples.

### EMBODIMENTS OF THE INVENTION

### Ultraviolet-Curable Resin Composition

One ultraviolet-curable resin composition of the present embodiment comprises: (A) at least one polymer selected from the group consisting of poly(meth)acrylates (a1) (hereinafter referred to as component (a1)) and polyvinyl ethers (a2) (hereinafter referred to as component (a2)) (hereinafter referred to as component (A)); (B) a compound having at least two secondary thiol groups in a molecule thereof (hereinafter referred to as component (B)); (C) a photopolymerization initiator a solution of which in acetonitrile with a concentration of 500 ppm has an absorbance of 0.50 or more in an optical path length of 10 mm at 385 nm (hereinafter referred to as component (C)); and (D) an organic compound that emits light upon absorbing ultraviolet rays, having a maximum wavelength of an absorption spectrum in a range of 300 nm or more and 450 nm or less, and having a maximum wavelength of an emission spectrum in a range of 350 nm or more and 500 nm or less (hereinafter referred to as component (D)).

In the present application, “(meth)acrylic” means “at least one selected from the group consisting of acrylic and methacrylic”. Similarly, “(meth)acrylate” means “at least one selected from the group consisting of acrylate and methacrylate”, and “(meth)acryloyl group” means “at least one selected from the group consisting of an acryloyl group and a methacryloyl group”.

<Poly(meth)acrylate (a1)>

As the component (a1), various known compounds can be used without any particular limitation as long as the compounds are compounds having at least two (meth) acryloyl groups in the molecule. The component (a1) may be used singly or two or more kinds thereof may be used in combination. In addition, it is an adoptable embodiment that the poly(meth)acrylate of the present embodiment is used together with a polyvinyl ether described later. Even when the poly(meth)acrylate and the polyvinyl ether are used together, the same effect as the effect of the present invention can be exhibited.

Typical examples of the component (a1) include, but are not limited to, alkylene glycol poly(meth)acrylates, polyalkylene glycol poly(meth)acrylates, glycerin poly(meth)acrylate, polyglycerin poly(meth)acrylate, pentaerythritol poly(meth)acrylate, polypentaerythritol poly(meth)acrylate, trimethylolpropane poly(meth)acrylate, polymethylolpropane poly(meth)acrylate, isocyanuric acid ethylene oxide-modified di(meth)acrylate, isocyanuric acid ethylene oxide-modified tri(meth)acrylate, isocyanuric acid propylene oxide-modified di(meth)acrylate, isocyanuric acid propylene oxide-modified tri(meth)acrylate, tricyclodecane dimethanol di(meth)acrylate, urethane(meth)acrylate, polyester(meth)acrylates, epoxy (meth)acrylate, polyether(meth)acrylates, and polyacrylic(meth)acrylate.

Typical examples of the alkylene glycol poly(meth)acrylate include, but are not limited to, ethylene glycol di(meth)acrylate, propylene glycol di(meth)acrylate, butylene glycol di(meth)acrylate, neopentyl glycol di(meth)acrylate, and 1,6-hexanediol di(meth)acrylate.

Typical examples of the polyalkylene glycol poly(meth)acrylate include, but are not limited to, diethylene glycol di(meth)acrylate, tetraethylene glycol di(meth)acrylate, polyethylene glycol di(meth)acrylate, dipropylene glycol di(meth)acrylate, and polypropylene glycol di(meth)acrylate.

Typical examples of the glycerin poly(meth)acrylate include, but are not limited to, glycerin di(meth)acrylate, glycerin tri(meth)acrylate, ethylene oxide-modified glycerin di(meth)acrylate, propylene oxide-modified glycerin di(meth)acrylate, ethylene oxide-modified glycerin tri(meth)acrylate, propylene oxide-modified glycerin tri(meth)acrylate, and mixtures of at least two polymers selected from the group consisting of glycerin mono(meth)acrylate, glycerin di(meth)acrylate, and glycerin tri(meth)acrylate.

Typical examples of the polyglycerin poly(meth)acrylate include, but are not limited to, diglycerin di(meth)acrylate, diglycerin tri(meth)acrylate, diglycerin tetra(meth)acrylate, triglycerin di(meth)acrylate, triglycerin tri(meth)acrylate, triglycerin tetra(meth)acrylate, and triglycerin penta(meth)acrylate.

Typical examples of the pentaerythritol poly(meth)acrylate include, but are not limited to, pentaerythritol di(meth)acrylate, pentaerythritol tri(meth)acrylate, pentaerythritol tetra(meth)acrylate, ethylene oxide-modified pentaerythritol di(meth)acrylate, propylene oxide-modified pentaerythritol di(meth)acrylate, ethylene oxide-modified pentaerythritol tri(meth)acrylate, propylene oxide-modified pentaerythritol tri(meth)acrylate, ethylene oxide-modified pentaerythritol tetra(meth)acrylate, propylene oxide-modified pentaerythritol tetra(meth)acrylate, and mixtures of at least two polymers selected from the group consisting of pentaerythritol mono(meth)acrylate, pentaerythritol di(meth)acrylate, pentaerythritol tri(meth)acrylate, and pentaerythritol tetra(meth)acrylate.

Typical examples of the polypentaerythritol poly(meth)acrylate include, but are not limited to, dipentaerythritol di(meth)acrylate, dipentaerythritol tri(meth)acrylate, dipentaerythritol tetra(meth)acrylate, dipentaerythritol penta(meth)acrylate, dipentaerythritol hexa(meth)acrylate, tripentaerythritol di(meth)acrylate, tripentaerythritol tri(meth)acrylate, tripentaerythritol tetra(meth)acrylate, tripentaerythritol penta(meth)acrylate, tripentaerythritol hexa(meth)acrylate, tripentaerythritol hepta(meth)acrylate, mixtures composed of at least two polymers selected from these(meth)acrylates, and a mixture of dipentaerythritol penta(meth)acrylate and dipentaerythritol hexa(meth)acrylate.

Typical examples of the trimethylolpropane poly(meth)acrylate include, but are not limited to, trimethylolpropane di(meth)acrylate, trimethylolpropane tri(meth)acrylate, ethylene oxide-modified trimethylolpropane di(meth)acrylate, propylene oxide-modified trimethylolpropane di(meth)acrylate, ethylene oxide-modified trimethylolpropane tri(meth)acrylate, and propylene oxide-modified trimethylolpropane tri(meth)acrylate.

Typical examples of the polytrimethylolpropane poly(meth)acrylate include, but are not limited to, ditrimethylolpropane di(meth)acrylate, ditrimethylolpropane tri(meth)acrylate, and ditrimethylolpropane tetra(meth)acrylate.

### (Urethane(meth)acrylate)

Typical examples of the urethane(meth)acrylate include, but are not limited to, a reaction product of a hydroxy group-containing(meth)acrylate and a polyisocyanate, and a reaction product of a hydroxy group-containing(meth)acrylate, a polyol, and a polyisocyanate.

As the hydroxy group-containing(meth)acrylate, various known compounds can be used without any particular limitation as long as the compounds have at least one hydroxy group in the molecule. The hydroxy group-containing(meth)acrylate may be used singly or two or more kinds thereof may be used in combination.

Typical examples of the hydroxy group-containing(meth)acrylate include, but are not limited to, hydroxy group-containing mono(meth)acrylates and hydroxy group-containing poly(meth)acrylates.

Typical examples of the hydroxy group-containing mono(meth)acrylate include, but are not limited to, hydroxy group-containing linear alkyl(meth)acrylates, hydroxy group-containing branched alkyl(meth)acrylates, hydroxy group-containing cycloalkyl(meth)acrylates, hydroxy group-containing aryl(meth)acrylates, polyalkylene glycol mono(meth)acrylates, glycerin mono(meth)acrylates, ethylene oxide-modified glycerin mono(meth)acrylates, propylene oxide-modified glycerin mono(meth)acrylates, trimethylolpropane mono(meth)acrylates, and caprolactone adducts of these mono(meth)acrylates.

Typical examples of the hydroxy group-containing linear alkyl(meth)acrylate include, but are not limited to, 2-hydroxyethyl(meth)acrylate, 3-hydroxypropyl (meth) acrylate, and 4-hydroxybutyl(meth)acrylate.

Typical examples of the hydroxy group-containing branched alkyl (meth) acrylate include, but are not limited to, 2-hydroxypropyl(meth)acrylate, 2-hydroxybutyl(meth)acrylate, and 3-hydroxybutyl(meth)acrylate.

Typical examples of the hydroxy group-containing cycloalkyl(meth)acrylate include, but are not limited to, 1,4-cyclohexanedimethanol mono(meth)acrylate. Typical examples of the hydroxy group-containing aryl(meth)acrylate include, but are not limited to, 1,4-benzenedimethanol mono(meth)acrylate.

Typical examples of the(meth)acrylates having an oxyalkylene chain, such as polyalkylene glycol mono(meth)acrylate include, but are not limited to, dipropylene glycol mono(meth)acrylate, diethylene glycol mono(meth)acrylate, polypropylene glycol mono(meth)acrylate, and polyethylene glycol mono(meth)acrylate; (meth)acrylates having an oxyalkylene chain having a block structure, such as polyethylene glycol-polypropylene glycol mono(meth)acrylate and polyoxybutylene-polyoxypropylene mono(meth)acrylate; (meth)acrylates having an oxyalkylene chain having a random structure, such as poly(ethylene glycol-tetramethylene glycol) mono(meth)acrylate and poly(propylene glycol-tetramethylene glycol) mono(meth)acrylate.

Typical examples of the hydroxy group-containing poly(meth)acrylate include, but are not limited to, compounds having at least one hydroxy group in the molecule among the alkylene glycol poly(meth)acrylates, the polyalkylene glycol poly(meth)acrylates, the glycerin poly(meth)acrylate, the polyglycerin poly(meth)acrylate, the pentaerythritol poly(meth)acrylate, the polypentaerythritol poly(meth)acrylate, the trimethylolpropane poly(meth)acrylate, and the polymethylolpropane poly(meth)acrylate.

Among the typical examples of the hydroxy group-containing (meth)acrylate, hydroxy group-containing (meth)acrylates having at least three (meth)acryloyl groups in the molecule are preferable, and hydroxy group-containing (meth)acrylates having one hydroxy group and at least three (meth)acryloyl groups in the molecule are more preferable from the viewpoint of being superior in curability and the scratch resistance of a cured film. The hydroxy group-containing (meth)acrylate is preferably a hydroxy group-containing pentaerythritol poly(meth)acrylate or a hydroxy group-containing polypentaerythritol poly(meth)acrylate from the viewpoint of being superior in curability and the scratch resistance of a cured film.

Among the typical examples of the polyisocyanate, various known compounds can be used without any particular limitation as long as the compounds have at least two isocyanate groups in the molecule. The polyisocyanate may be used singly, or two or more kinds thereof may be used in combination.

Typical examples of the polyisocyanate include, but are not limited to, a linear aliphatic diisocyanate, a branched aliphatic diisocyanate, an alicyclic diisocyanate, an aromatic diisocyanate, a biuret form, an isocyanurate form, an allophanate form, and an adduct form of these diisocyanates, and a complexes obtained by reacting two or more forms selected from the group consisting of a biuret form, an isocyanurate form, an allophanate form, and an adduct form.

Typical examples of the linear aliphatic diisocyanate include, but are not limited to, methylene diisocyanate, ethylene diisocyanate, propylene diisocyanate, tetramethylene diisocyanate, pentamethylene diisocyanate, hexamethylene diisocyanate, heptamethylene diisocyanate, octamethylene diisocyanate, nonamethylene diisocyanate, and decamethylene diisocyanate.

Typical examples of the branched aliphatic diisocyanate include, but are not limited to, diethylpentylene diisocyanate, trimethylbutylene diisocyanate, trimethylpentylene diisocyanate, and trimethylhexamethylene diisocyanate.

Typical examples of the alicyclic diisocyanate include, but are not limited to, hydrogenated xylene diisocyanate, hydrogenated diphenylmethane diisocyanate, isophorone diisocyanate, cyclopentylene diisocyanate, cyclohexylene diisocyanate, cycloheptylene diisocyanate, cyclodecylene diisocyanate, tricyclodecylene diisocyanate, adamantane diisocyanate, norbornene diisocyanate, and bicyclodecylene diisocyanate.

Typical examples of the aromatic diisocyanate include, but are not limited to, dialkyldiphenylmethane diisocyanates, such as 4,4′-diphenyldimethylmethane diisocyanate, tetraalkyldiphenylmethane diisocyanates, such as 4,4′-diphenyltetramethylmethane diisocyanate, 4,4′-diphenylmethane diisocyanate, 4,4′-dibenzyl isocyanate, 1,3-phenylene diisocyanate, 1,4-phenylene diisocyanate, tolylene diisocyanate, xylylene diisocyanate, m-tetramethylxylylene diisocyanate, and 1,5-naphthylene diisocyanate.

Typical examples of the biuret forms of the diisocyanates include, but are not limited to, compounds represented by the following structural formula:

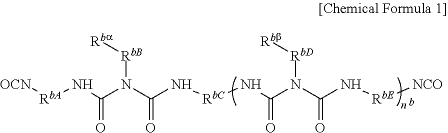

wherein n^{b} is an integer of 1 or more, R^{bA} to R^{bE} are each independently any one member or two or more members selected from the group consisting of a linear aliphatic diisocyanate residue, a branched aliphatic diisocyanate residue, an alicyclic diisocyanate residue, and an aromatic diisocyanate residue, and Rba to Rbf are each independently an isocyanate group or

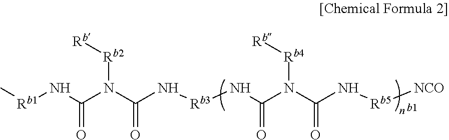

wherein nb¹ is an integer of 0 or more, R^{b1} to R^{b5} are the same as R^{bA} to R^{bE} and R^{b}′ to R^{b}″ are each independently an isocyanate group or a group of R^{bα} to R^{bβ} itself, the groups of R^{b4} to R^{b5} and R^{b}″ may be different for each constituent unit; the groups of R^{bD} to R^{bE} and R^{bβ} may be different for each constituent unit.

Typical examples of the biuret forms of the diisocyanates include, but are not limited to, DURANATE 24A-100, DURANATE 22A-75P, DURANATE 21S-75E (manufactured by Asahi Kasei Corporation), and Desmodur N3200A (biuret form of hexamethylene diisocyanate) (manufactured by Sumika Covestro Urethane Co., Ltd.).

Typical examples of the isocyanurate forms of the diisocyanates include, but are not limited to, compounds represented by the following structural formula:

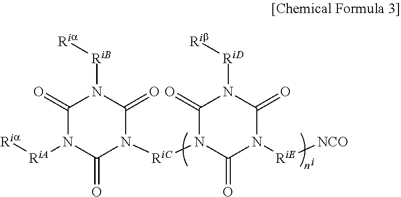

wherein nⁱ is an integer of 0 or more, R^{iA} to R^{iE} are each independently any one member or two or more members selected from the group consisting of a linear aliphatic diisocyanate residue, a branched aliphatic diisocyanate residue, an alicyclic diisocyanate residue, and an aromatic diisocyanate residue, and R^{iα} to R^{iβ} are each independently an isocyanate group or

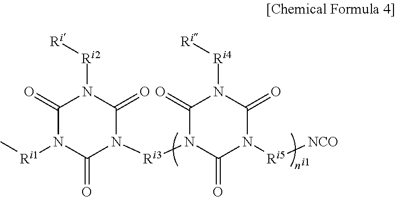

wherein nⁱ¹ is an integer of 0 or more, Rⁱ¹ to Rⁱ⁵ are the same as R^{iA} to R^{iE}, and Rⁱ′ to Rⁱ″ are each independently an isocyanate group or a group of R^{iα} to R^{iβ} itself, the groups of Rⁱ⁵ and Rⁱ″ may be different for each constituent unit;
the groups of R^{iD} to R^{iE} and R^{iβ} may be different for each constituent unit.

Typical examples of the isocyanurate forms of the diisocyanates include, but are not limited to, DURANATE TPA-100, DURANATE TKA-100, DURANATE MFA-75B, DURANATE MHG-80B (manufactured by Asahi Kasei Corporation), Coronate HXR, Coronate HX (isocyanurate forms of hexamethylene diisocyanate) (manufactured by Tosoh Corporation), TAKENATE D-127N (isocyanurate form of hydrogenated xylylene diisocyanate) (manufactured by Mitsui Chemicals, Inc.), and VESTANAT T1890/100 (isocyanurate form of isophorone diisocyanate) (manufactured by Evonik Japan Co., Ltd.).

Typical examples of the allophanate forms of the diisocyanates include, but are not limited to, compounds represented by the following structural formula:

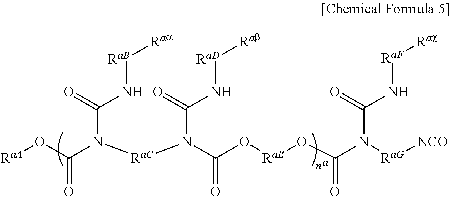

wherein n^{a} is an integer of 0 or more, R^{aA} is an alkyl group, an aryl group, a polyether group, a polyester group, or a polycarbonate group, R^{aB} to R^{aG} are each independently any one member or two or more members selected from the group consisting of a linear aliphatic diisocyanate residue, a branched aliphatic diisocyanate residue, an alicyclic diisocyanate residue, and an aromatic diisocyanate residue, and R^{aα} to R^{aγ} are each independently an isocyanate group or

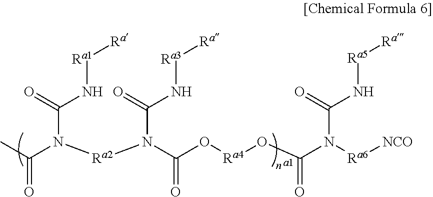

wherein nal is an integer of 0 or more, R^{a1} to R^{a6} are the same as R^{aB} to R^{aG}, and R^{a}′ to R^{a}″ are each independently an isocyanate group or a group of R^{aα} to R^{aγ} itself,
the groups of R^{a1} to R^{a4} and R^{a}′ to R^{a}″ may be different for each constituent unit; the groups of R^{aB} to R^{aE} and R^{aα} to R^{aγ} may be different for each constituent unit.

Typical examples of the allophanate forms of the diisocyanates include, but are not limited to, Coronate 2793 (manufactured by Tosoh Corporation) and TAKENATE D-178N (manufactured by Mitsui Chemicals, Inc.).

Typical examples of the adducts of the diisocyanates include, but are not limited to, adduct forms of trimethylolpropane and diisocyanate represented by the following structural formula:

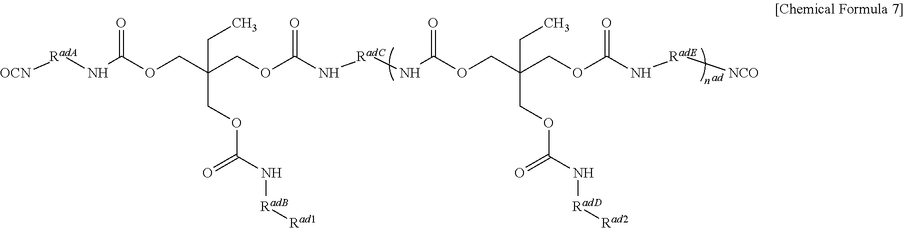

wherein nad is an integer of 0 or more, R^{adA} to R^{adE} are each independently any one member or two or more members selected from the group consisting of a linear aliphatic diisocyanate residue, a branched aliphatic diisocyanate residue, an alicyclic diisocyanate residue, and an aromatic diisocyanate residue, and R^{ad1} to R^{ad2} are each independently

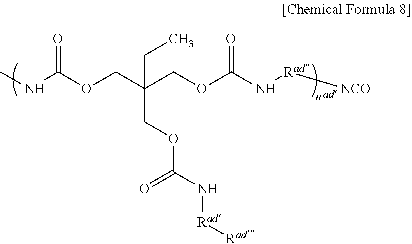

wherein n^{ad}′ is an integer of 0 or more, R^{ad}′ to R^{ad}″ are the same as R^{adA} to R^{adE}, R^{ad}″ is a group of R^{ad1} to R^{ad2} itself, and R^{ad}′ to R^{ad}″ may have different groups for each constituent unit,
the groups of R^{adD} to R^{adE} and R^{ad2} may be different for each constituent unit; and
an adduct of glycerin and diisocyanate represented by the following structural formula:

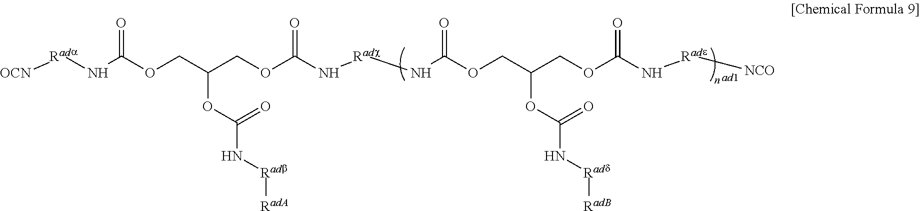

wherein n^{ad1} is an integer of 0 or more, R^{adα} to R^{adϵ} are each independently any one member or two or more members selected from the group consisting of a linear aliphatic diisocyanate residue, a branched aliphatic diisocyanate residue, an alicyclic diisocyanate residue, and an aromatic diisocyanate residue, and R^{adA} to R^{adB} are each independently

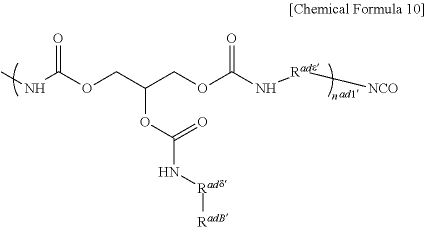

wherein n^{ad1}′ is an integer of 0 or more, R^{adδ}′ to R^{adϵ}′ are the same as R^{adα} to R^{adϵ}, R^{adB}′ is a group of R^{adA} to R^{adB} itself, and R^{adδ}′ to R^{adϵ}′ and R^{adB}′ may be different groups for each constituent unit,
the groups of R^{adδ} to R^{adϵ} may be different for each constituent unit.

Typical examples of the adducts of the diisocyanates include, but are not limited to, DURANATE P301-75E (manufactured by Asahi Kasei Corporation), TAKENATE D-110N, TAKENATE D-160N (manufactured by Mitsui Chemicals, Inc.), Coronate L and Coronate HL (manufactured by Tosoh Corporation).

In each of the above formulas, “a linear aliphatic diisocyanate residue, a branched aliphatic diisocyanate residue, an alicyclic diisocyanate residue, and an aromatic diisocyanate residue” means remaining groups formed by removing isocyanate groups from the linear aliphatic diisocyanate, the branched aliphatic diisocyanate, the alicyclic diisocyanate, and the aromatic diisocyanate.

The polyisocyanate is preferably a polyisocyanate having at least three isocyanate groups in the molecule from the viewpoint of being superior in the scratch resistance of a cured film. As the polyisocyanate having at least three isocyanate groups in the molecule, the biuret form, the isocyanurate form, the allophanate form, and the adduct form are preferable.

As the polyol, various known compounds can be used without any particular limitation as long as the compounds are compounds having at least two hydroxy groups in the molecule. The polyol may be used singly, or two or more kinds thereof may be used in combination.

Typical examples of the polyol include, but are not limited to, an aliphatic polyol, an alicyclic polyol, a polyether-based polyol, a polyester-based polyol, a polycarbonate-based polyol, a polyolefin-based polyol, a polybutadiene-based polyol, and a(meth)acrylic polyol.

Typical examples of the aliphatic polyol include, but are not limited to, aliphatic alcohols containing two hydroxy groups such as ethylene glycol, diethylene glycol, propylene glycol, dipropylene glycol, trimethylene glycol, dimethylolpropane, neopentyl glycol, 2,2-diethyl-1,3-propanediol, 2-butyl-2-ethyl-1,3-propanediol, 1,4-tetramethylenediol, 1,3-tetramethylenediol, 2-methyl-1,3-trimethylenediol, 1,5-pentamethylenediol, 1,6-hexamethylenediol, 3-methyl-1,5-pentamethylenediol, 2,4-diethyl-1,5-pentamethylenediol, pentaerythritol diacrylate, 1,9-nonanediol, and 2-methyl-1,8-octanediol, sugar alcohols such as xylitol and sorbitol, and aliphatic alcohols containing three or more hydroxy groups such as glycerin, trimethylolpropane, and trimethylolethane.

Typical examples of the alicyclic polyol include, but are not limited to, cyclohexanediols such as 1,4-cyclohexanediol and cyclohexyldimethanol, hydrogenated bisphenols such as hydrogenated bisphenol A, and tricyclodecane dimethanol.

Typical examples of the polyether-based polyol include, but are not limited to, polyalkylene glycols, such as polyethylene glycol, polypropylene glycol, polytetramethylene glycol, polybutylene glycol, polypentamethylene glycol, and polyhexamethylene glycol, and random or block copolymers of these polyalkylene glycols.

Typical examples of the polyester-based polyol include, but are not limited to, polycondensates of a polyhydric alcohol with a polyvalent carboxylic acid or an anhydride thereof; ring-opening polymers of cyclic esters (lactones); and reaction products of three components of a polyhydric alcohol, a polyvalent carboxylic acid or an anhydride thereof, and a cyclic ester.

Typical examples of the polyhydric alcohol include, but are not limited to, ethylene glycol, diethylene glycol, propylene glycol, dipropylene glycol, trimethylene glycol, 1,4-tetramethylenediol, 1,3-tetramethylenediol, 2-methyl-1,3-trimethylenediol, 1,5-pentamethylenediol, neopentyl glycol, 1,6-hexamethylenediol, 3-methyl-1,5-pentamethylenediol, 2,4-diethyl-1,5-pentamethylenediol, glycerin, trimethylolpropane, trimethylolethane, cyclohexanediols, such as 1,4-cyclohexanediol, bisphenols, such as bisphenol A, sugar alcohols, such as xylitol and sorbitol.

Typical examples of the polycarboxylic acid or an anhydride thereof include, but are not limited to, aliphatic dicarboxylic acids, such as malonic acid, maleic acid, fumaric acid, succinic acid, glutaric acid, adipic acid, suberic acid, azelaic acid, sebacic acid, and dodecanedionic acid, alicyclic dicarboxylic acids, such as 1,4-cyclohexanedicarboxylic acid, aromatic dicarboxylic acids, such as terephthalic acid, isophthalic acid, orthophthalic acid, 2,6-naphthalenedicarboxylic acid, paraphenylenedicarboxylic acid, and trimellitic acid, and anhydrides thereof.

Typical examples of the cyclic ester include, but are not limited to, propiolactone, butyrolactone, valerolactone, β-methyl-δ-valerolactone, and ϵ-caprolactone.

Typical examples of the polycarbonate-based polyol include, but are not limited to, a reaction product of a polyhydric alcohol with phosgene; and a ring-opening polymer of a cyclic carbonate, such as alkylene carbonate.

Typical examples of the polyhydric alcohol include the polyhydric alcohols recited as examples for the polyester-based polyol, and specifically include, but are not limited to, the alkylene carbonates, ethylene carbonate, trimethylene carbonate, tetramethylene carbonate, and hexamethylene carbonate.

The polycarbonate polyol may be any compound having a carbonate linkage in the molecule and a hydroxy group at a terminal, and may have an ester linkage together with the carbonate linkage.

Typical examples of the polyolefin-based polyol include, but are not limited to, those having a homopolymer or copolymer of ethylene, propylene, or butene as a saturated hydrocarbon skeleton and having a hydroxy group at a molecular terminal thereof.

Typical examples of the polybutadiene-based polyol include, but are not limited to, compounds having a copolymer of butadiene as a hydrocarbon skeleton and having a hydroxy group at a molecular terminal thereof. The polybutadiene-based polyol may be a hydrogenated polybutadiene polyol in which all or a part of ethylenically unsaturated groups contained in the structure thereof are hydrogenated.

Typical examples of the(meth)acrylic polyol include, but are not limited to, compounds having at least two hydroxy groups in the molecule of a polymer or copolymer of a (meth)acrylic acid ester. Typical examples of the(meth)acrylic acid ester include, but are not limited to, (meth)acrylic acid alkyl esters, such as methyl (meth)acrylate, ethyl(meth)acrylate, propyl(meth)acrylate, butyl(meth)acrylate, hexyl (meth)acrylate, octyl(meth)acrylate, 2-ethylhexyl(meth)acrylate, decyl(meth)acrylate, dodecyl (meth)acrylate, and octadecyl(meth)acrylate.

In the urethane(meth)acrylate, the molar ratio (NCO:OH) of the isocyanate groups contained in the polyisocyanate and the hydroxy groups contained in the hydroxy group-containing (meth)acrylate and the hydroxy group contained in the polyol is not particularly limited. The ratio is preferably 1:1 to 10, more preferably about 1:1 to 8 from the viewpoint of being superior in the balance between the flexibility and the scratch resistance of a cured film.

The method for producing the urethane (meth)acrylate is not particularly limited as long as it is a method of reacting the hydroxy group-containing (meth)acrylate, the polyisocyanate, and as necessary, the polyol, and various known production methods can be disclosed as examples. In a specific example, a method of reacting a hydroxy group-containing (meth)acrylate, a polyisocyanate, and as necessary a polyol at an appropriate reaction temperature (for example, 60° C. to 90° C.) in the presence of a catalyst, and the like can be adopted. In addition, the order of reacting the hydroxy group-containing (meth)acrylate, the polyisocyanate, and the polyol is not particularly limited, and a method of mixing the hydroxy group-containing (meth)acrylate, the polyisocyanate, and the polyol in an arbitrary order to cause a reaction, a method of mixing all the components at once to cause a reaction, and the like can be adopted, but the order is not limited thereto.

Typical examples of the catalyst include, but are not limited to, organic tin catalysts, such as dibutyltin dilaurate and dioctyltin dilaurate, organic acid tin, such as tin octylate, organic titanium catalysts, such as titanium ethyl acetoacetate, organic zirconium catalysts, such as zirconium tetraacetylacetonate, and organic iron catalysts, such as iron acetylacetonate. The catalyst may be used singly, or two or more kinds thereof may be used in combination.

(Polyester (meth)acrylate)

Typical examples of the polyester (meth)acrylate include, but are not limited to, a dehydration condensate of the polyester-based polyol with (meth)acrylic acid.

(Epoxy (meth)acrylate)

Typical examples of the epoxy (meth)acrylate include, but are not limited to, a compound obtained via an addition reaction between a terminal epoxy group of an epoxy resin and (meth)acrylic acid. Typical examples of the epoxy resin include, but are not limited to, aromatic epoxy resins and aliphatic epoxy resins.

Typical examples of the aromatic epoxy resin include, but are not limited to, a bisphenol A epoxy resin, a bisphenol F epoxy resin, a biphenol epoxy resin, a phenol novolac epoxy resin, a cresol novolac epoxy resin, a bisphenol A novolac epoxy resin, a naphthalenediol epoxy resin, a phenol dicyclopentadiene novolac epoxy resin, and hydrides thereof.

Typical examples of the aliphatic epoxy resin include, but are not limited to, diglycidyl ethers of alkylene glycols such as ethylene glycol, propylene glycol, 1,4-butanediol, and 1,6-hexanediol; diglycidyl ethers of polyalkylene glycols, such as diglycidyl ethers of polyethylene glycol and polypropylene glycol; diglycidyl ethers of neopentyl glycol, dibromoneopentyl glycol, and alkylene oxide adducts thereof; polyglycidyl ethers of polyhydric alcohols, such as di- or triglycidyl ethers of trimethylolethane, trimethylolpropane, glycerin, and alkylene oxide adducts thereof, and di-, tri- or tetraglycidyl ethers of pentaerythritol and alkylene oxide adducts thereof; di- or polyglycidyl ethers of hydrogenated bisphenol A and alkylene oxide adducts thereof; tetrahydrophthalic acid diglycidyl ether; and hydroquinone diglycidyl ether.

(Polyether (meth)acrylate)

Typical examples of the polyether (meth)acrylate include, but are not limited to, a dehydration condensate of the polyether-based polyol with (meth)acrylic acid.

(Polyacrylic (meth)acrylate)

Typical examples of the polyacrylic (meth)acrylate include, but are not limited to, a reaction product of (meth)acrylic acid with an acrylic copolymer obtained by polymerizing an epoxy group-containing mono(meth)acrylate and, as necessary, a mono(meth)acrylate.

Typical examples of the epoxy group-containing mono(meth)acrylate include, but are not limited to, glycidyl (meth)acrylate, β-methylglycidyl(meth)acrylate, 3,4-epoxycyclohexylmethyl (meth)acrylate, and vinylcyclohexene monooxide (namely, 1,2-epoxy-4- vinylcyclohexane).

The component (a1) is preferably trimethylolpropane poly(meth)acrylate, ditrimethylolpropane poly(meth)acrylate, pentaerythritol(poly)acrylate, or dipentaerythritol poly(meth)acrylate from the viewpoint of curability.

<Polyvinyl ether (a2)>

In addition, as the component (a2), various known compounds can be used without any particular limitation as long as the compounds are vinyl ether-based compounds having at least two vinyl groups in the molecule.

Typical examples of the component (a2) include, but are not limited to, ethylene glycol divinyl ether, diethylene glycol divinyl ether, polyethylene glycol divinyl ether, propylene glycol divinyl ether, butylene glycol divinyl ether, hexanediol divinyl ether bisphenol A alkylene oxide divinyl ether, bisphenol F alkylene oxide divinyl ether, trimethylolpropane trivinyl ether, ditrimethylolpropane tetravinyl ether, glycerin trivinyl ether, pentaerythritol tetravinyl ether, dipentaerythritol pentavinyl ether, and dipentaerythritol hexavinyl ether.

(Physical Properties of poly(meth)acrylate (a1))

The physical properties of the component (a1) are not particularly limited. The number of the (meth)acryloyl groups in the molecule of the component (a1) is preferably at least 3 from the viewpoint of being superior in the hardness of a cured film, and more preferably 3 to 15 from the same point of view.

The content of the component (a1) in the ultraviolet-curable resin composition is not particularly limited, but is preferably 25 mass % or more and 85 mass % or less based on 100 mass % of the ultraviolet-curable resin composition in terms of solid content from the viewpoint of being superior in wet heat resistance and appearance.

(Physical Properties of Polyvinyl Ether (a2))

The physical properties of the component (a2) are not particularly limited. The number of the vinyl groups in the molecule in the component (a2) is preferably at least 3 from the viewpoint of being superior in the hardness of a cured film, and more preferably 3 to 15 from the same point of view.

The content of the component (a2) in the ultraviolet-curable resin composition is not particularly limited, but is preferably 25 mass % or more and 85 mass % or less based on 100 mass % of the ultraviolet-curable resin composition in terms of solid content from the viewpoint of being superior in wet heat resistance and appearance.

<Compound (B) having at Least Two Secondary Thiol Groups in the Molecule>

As the component (B), various known compounds can be used without any particular limitation as long as the compounds are compounds having at least two secondary thiol groups in the molecule. The component (B) may be used singly or two or more kinds thereof may be used in combination.

Thanks to that the component (B) has a secondary thiol group, the ultraviolet-curable resin composition is superior in the curability of a shielding portion and a deep portion. When a compound having a primary thiol group in the molecule is used instead of the component (B), curing of a shielding portion and a deep portion in the ultraviolet-curable resin composition proceeds insufficiently. In addition, thanks to that the component (B) has at least two secondary thiol groups in the molecule, the ultraviolet-curable resin composition is superior in the curability of a shielding portion and a deep portion, but when a compound having one secondary thiol group in the molecule is used, curing of the shielding portion and the deep portion in the ultraviolet-curable resin composition proceeds insufficiently.

Typical examples of the component (B) include, but are not limited to, compounds represented by the following general formula (1).

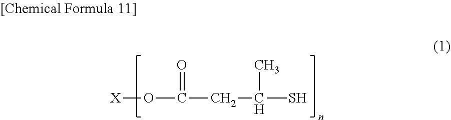

wherein X represents an n-valent organic group, and n represents an integer of 2 to 6.

Typical examples of the component (B) include, but are not limited to, 1,4-bis(3-mercaptobutyryloxy) butane, 1,3,5-tris(3-mercaptobutyryloxyethyl)-1,3,5-triazine-2,4,6(1H,3H,5H)-trione, trimethylolpropane tris(3-mercaptobutyrate), and pentaerythritol tetrakis(3-mercaptobutyrate).

The component (B) is more preferably at least one compound selected from the group consisting of 1,3,5-tris(3-mercaptobutyryloxyethyl)-1,3,5-triazine-2,4,6(1H,3H,5H)-trione, trimethylolpropane tris(3-mercaptobutyrate), and pentaerythritol tetrakis (3-mercaptobutyrate) from the viewpoint of being superior in curability in a shielding portion and a deep portion.

(Physical Properties of Compound (B) having at Last Two Secondary Thiol Groups in Molecule)

The physical properties of the component (B) are not particularly limited. The number of the secondary thiol groups in the molecule in the component (B) is preferably at least 3 from the viewpoint of being superior in curability in a shielding portion and a deep portion, and more preferably 3 to 4 from the same point of view.

A typical example of the content of the component (B) in the ultraviolet-curable resin composition is 10 mass % or more (in a narrower sense, more than 10 mass %) and 70 mass % or less (in a narrower sense, less than 70 mass %) based on 100 mass % of the ultraviolet-curable resin composition in terms of solid content. When the content of the component (B) is 10 mass % or more (in a narrower sense, more than 10 mass %), the ultraviolet-curable resin composition is superior in curability in a shielding portion and a deep portion. From the viewpoint of more reliably enhancing the curability in a shielding portion and a deep portion, the lower limit value of the above numerical range is preferably 30 mass % or more (in a narrower sense, more than 30 mass %), and more preferably 50 mass % or more (in a narrower sense, more than 50 mass %). On the other hand, when the content of the component (B) is 70 mass % or less (in a narrower sense, less than 70 mass %), a cured product is superior in chemical resistance. From the viewpoint of more reliably enhancing the chemical resistance of the cured product, the upper limit value in the above-mentioned numerical range is preferably 40 mass % or less (in a narrower sense, less than 40 mass %), and more preferably 20 mass % or less (in a narrower sense, less than 20 mass %). Therefore, more suitable numerical values can be obtained for the upper limit value and the lower limit value on the basis of mutually independent points of view. For example, when more suitable numerical values are assigned to both the upper limit value and the lower limit value, one suitable numerical value range for the content of the component (B) is 20 mass % or more (in a narrower sense, more than 20 mass %) and 50 mass % or less (in a narrower sense, less than 50 mass %). Further, when more suitable numerical values are assigned to both the upper limit value and the lower limit value, one suitable numerical value range for the content of the component (B) is 40 mass % or more (in a narrower sense, more than 40 mass %) and 50 mass % or less (in a narrower sense, less than 50 mass %).

The content of the component (B) in the ultraviolet-curable resin composition is preferably 25 mass % or more and 70 mass % or less based on 100 mass % of the ultraviolet-curable resin composition in terms of solid content from the viewpoint of being superior in curability in a shielding portion and a deep portion, and more preferably 35 mass % or more and 70 mass % or less from the same point of view.

In the ultraviolet-curable resin composition, the molar ratio of the (meth) acryloyl groups contained in the component (a1) to the secondary thiol groups contained in the component (B) ((meth)acryloyl group: thiol group) is not particularly limited, but is preferably 1:0.5 to 1.5 and more preferably 1:0.8 to 1.2 from the viewpoint of being superior in curability in a shielding portion and a deep portion.

In the ultraviolet-curable resin composition, the molar ratio of the vinyl groups contained in the component (a2) and the thiol groups contained in the component (B) (vinyl group: thiol group) is not particularly limited, but is preferably 1:0.5 to 1.5 and more preferably 1:0.8 to 1.2 from the viewpoint of being superior in curability in a shielding portion and a deep portion.

### <Photopolymerization Initiator (C)>

As the component (C), various known photopolymerization initiators can be used without any particular limitation as long as a solution thereof in acetonitrile with a concentration of 500 ppm has an absorbance of 0.50 or more in an optical path length of 10 mm at 385 nm. The component (C) may be used singly or two or more kinds thereof may be used in combination.

Typical examples of the component (C) include, but are not limited to, an acylphosphine oxide compound.

Typical examples of the acylphosphine oxide compound include, but are not limited to, 2,4,6-trimethylbenzoyldiphenylphosphine oxide, 2,4,6-trimethylbenzoylphenylethoxyphosphine oxide, bis(2,4,6-trimethylbenzoyl)-phenylphosphine oxide, and bis(2,6-dimethoxybenzoyl)-2,4,4-trimethyl-pentylphosphine oxide.

The component (C) is preferably an acylphosphine oxide compound from the viewpoint of being superior in curability in a shielding portion and a deep portion. From the same viewpoint as described above, the component (C) is more preferably at least one compound selected from the group consisting of 2,4,6-trimethylbenzoyldiphenylphosphine oxide, 2,4,6-trimethylbenzoylphenylethoxyphosphine oxide, bis(2,4,6-trimethylbenzoyl)-phenylphosphine oxide, and bis(2,6-dimethoxybenzoyl)-2,4,4-trimethyl-pentylphosphine oxide.

### (Physical Properties of Photopolymerization Initiator (C))

As to the component (C), the absorbance of a solution thereof in acetonitrile with a concentration of 500 ppm in an optical path length of 10 mm is 0.50 or more at 385 nm. The absorbance of the component (C) at 385 nm is determined by preparing a solution (concentration: 500 ppm) of the component (C) in acetonitrile, and measuring the absorbance at 385 nm with a spectrophotometer using a two-face translucent quartz cell having an optical path length of 10 mm. As the spectrophotometer, a commercially available product can be used.

The ultraviolet-curable resin composition sufficiently cures in a shielding portion and a deep portion owing to the use of the component (C). Although the details of this are unknown, it is presumed that since the component (C) has an absorbance at 385 nm of 0.50 or more, the component (C) can satisfactorily absorb light emitted from the component (D) described later, and therefore a polymerization initiating action (radical generation reaction) of the component (C) existing in a shielding portion and a deep portion is sufficiently exerted, and curing in the shielding portion and the deep portion sufficiently proceeds in the ultraviolet-curable resin composition.

In recent years, from the viewpoint of energy saving and space saving, a light emitting diode (UV-LED) has been desired as an ultraviolet (UV) light source in ultraviolet curing. However, since the UV-LED has relatively low energy, curing may be insufficient. When the absorbance of the component (C) at 385 nm is 0.5 or more, the component has sufficient absorption for ultraviolet rays emitted by a UV-LED light source (350 nm to 420 nm), so that the ultraviolet-curable resin composition can be sufficiently cured even when a UV-LED is used.

Physical properties of the component (C) other than the absorbance at 385 nm are not particularly limited.

The content of the component (C) in the ultraviolet-curable resin composition is not particularly limited. From the viewpoint of being superior in curability in a shielding portion and a deep portion, the content is preferably 0.1 mass % or more (in a narrower sense, more than 0.1 mass %) and 15 mass % or less (in a narrower sense, less than 15 mass %), and more preferably 0.1 mass % or more (in a narrower sense, more than 0.1 mass %) and 5 mass % or less (in a narrower sense, less than 5% by mass) based on 100 mass % of the ultraviolet-curable resin composition in terms of solid content.

<Organic Compound (D) that Emits Light Upon Absorbing Ultraviolet Rays>

As the component (D), various known organic compounds can be used without any particular limitation as long as the organic compounds have a maximum wavelength of an absorption spectrum in a range of 300 nm or more and 450 nm or less, have a maximum wavelength of an emission spectrum in a range of 350 nm or more and 500 nm or less, and emit light upon absorbing ultraviolet rays. The component (D) may be used singly or two or more kinds thereof may be used in combination.

Typical examples of the component (D) include, but are not limited to, an anthracene compound, a coumarin compound, a carbazole compound, a benzoxazole compound, a naphthalene compound, a stilbene compound, an oxadiazole compound, a pyrene compound, and a perylene compound.

Typical examples of the anthracene compound include, but are not limited to, compounds having a skeleton represented by the following general formula (2).

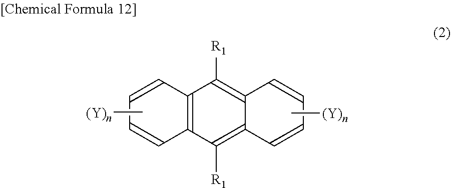

wherein R₁ independently at each occurrence represents a hydrogen atom, a phenyl group, a phenylmethylene group, a phenylethylene group, a phenylpropylene group or a phenylethynyl group, Y independently at each occurrence represents a hydrogen atom or a halogen atom, and n independently at each occurrence represents an integer of 1 to 4.

The phenyl group as R₁ of the above general formula (2) specifically has a structure represented by the following general formula (3).

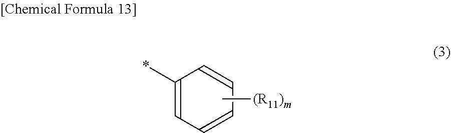

wherein R₁₁ independently at each occurrence represents a hydrogen atom or an alkyl group having 1 to 3 carbon atoms, m represents an integer of 1 to 5, and the symbol * represents a linking site to the skeleton represented by the general formula (2).

Specific examples of the phenylmethylene group, the phenylethylene group, the phenylpropylene group, and the phenylethynyl group as R₁ of the above general formula (2) include, but are not limited to, a phenylmethylene group, a phenylethylene group, a phenylpropylene group, and a phenylethynyl group in each of which the benzene ring has no substituent, or a phenylmethylene group, a phenylethylene group, a phenylpropylene group, and a phenylethynyl group each having an alkyl group having 1 to 3 carbon atoms as a substituent.

R₁ in the general formula (2) is particularly preferably a phenyl group represented by the general formula (3), and all of Y in the general formula (2) are preferably a hydrogen atom. In addition, all of R₁₁ in the general formula (3) are preferably a hydrogen atom.

Typical examples of the anthracene compound include, but are not limited to, halogenated anthracene, 9,10-diphenylanthracene, 9,10-bis(phenylethynyl)anthracene, and 2-chloro-9,10-bis(phenylethynyl) anthracene.

Typical examples of the coumarin compound include, but are not limited to, coumarin, 7-hydroxy-4-methylcoumarin, 4-hydroxy-7-methylcoumarin, 3-(2-benzimidazolyl)-7-(diethylamino)coumarin, 3-(2-benzothiazolyl)-7-(diethylamino)coumarin, 7-diethylamino-4-methylcoumarin, 3-phenyl-7-aminocoumarin, 3-phenyl-7-(imino-1′,3′,5′-triazine-2′-diethylamino-4′-chloro)coumarin, 3-phenyl-7-naphthotriazole coumarin, and 7-(4′-chloro-6″-diethylamino-1′,3′,5′-triazin-4′-yl) amino-3-phenylcoumarin.

Typical examples of the carbazole compound include, but are not limited to, 1,3,5-tri(9H-carbazol-9-yl)benzene, 4,4′-bis(9H-carbazol-9-yl) biphenyl, 9,9′-(2,2′-dimethylbiphenyl-4,4′-diyl)bis(9H-carbazole), and 9-phenylcarbazole.

Typical examples of the benzoxazole compound include, but are not limited to, compounds having a skeleton represented by the following general formula (4).

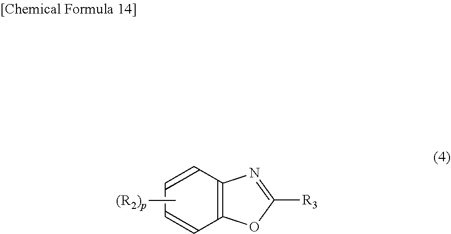

wherein R₂ independently at each occurrence represents a hydrogen atom or an alkyl group having 1 to 6 carbon atoms, and R₃ represents an alkylene group having 1 to 3 carbon atoms or a group represented by the following general formula (5):

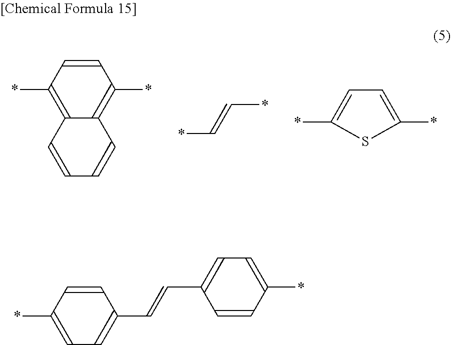

wherein the symbol * represents a linking site to the skeleton represented by the general formula (4)), and p represents an integer of 1 to 4.

R₂ in the general formula (4) is preferably an alkyl group having 1 to 6 carbon atoms, more preferably an alkyl group having a branched chain having 4 to 6 carbon atoms, and still more preferably a tert-butyl group. In addition, R₃ in the general formula (4) is preferably a group represented by the general formula (5).

Typical examples of the benzoxazole compound include, but are not limited to, 2,5-thiophenediyl(5-tert-butyl-1,3-benzoxazole), 2,2′-(thiophenediyl)-bis(tert-butyl-benzoxazole), 2,5-bis(6,6′-bis(tert-butyl)-benzoxazol-2-yl)thiophene 4-(benzoxazol-2-yl)-4′-(5-methylbenzoxazol-2-yl)stilbene, 4,4′-bis(benzoxazol-2-yl)stilbene, 2,4,4′-bis(benzoxazol-2-yl)furan, 1,2-bis(5-methyl-2-benzoxazolyl)ethylene, and 1,4-bis(2-benzoxazolyl)naphthalene.

Typical examples of the naphthalene compound include, but are not limited to, naphthalene.

Typical examples of the stilbene compound include, but are not limited to, a compound having a skeleton represented by the following general formula (6).

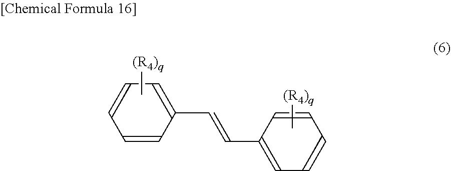

wherein R₄ independently at each occurrence represents a hydrogen atom or an alkyl group having 1 to 3 carbon atoms, and q independently at each occurrence represents an integer of 1 to 5.

All of R₄′s in the general formula (6) are preferably a hydrogen atom.

Typical examples of the stilbene compound include, but are not limited to, stilbene, trans-1,2-diphenylethylene, 4,4′-bis(diphenyltriazinyl)stilbene, stilbenyl-naphthotriazole, 4,4′-bis(diphenyltriazinyl)stilbene, stilbenyl-naphthotriazole, and phenyl 2-(stilbyl-4)-(naphtho-1′,2′,4,5)-1,2,3-triazole-2″-sulfonate.

Typical examples of the pyrene compound include, but are not limited to, pyrene and benzopyrene.

The component (D) is preferably at least one compound selected from the group consisting of benzoxazole compounds, naphthalene compounds, anthracene compounds, pyrene compounds, and stilbene compounds from the viewpoint of being superior in curability in a shielding portion and a deep portion, more preferably at least one compound selected from the group consisting of benzoxazole compounds, pyrene compounds, and stilbene compounds from the same point of view, and particularly preferably at least one compound selected from the group consisting of 2,5-thiophenediylbis(5-tert-butyl-1,3-benzoxazole) and pyrene from the same point of view.

### (Physical Properties of Organic Compound (D) That Emits Light Upon Absorbing Ultraviolet Rays)

The component (D) has a maximum wavelength of an absorption spectrum in a range of 300 nm or more and 450 nm or less and has a maximum wavelength of an emission spectrum in a range of 350 nm or more and 500 nm or less. The absorption spectrum and the emission spectrum of the component (D) can be confirmed by preparing a solution of the component (D) in DMF (dimethylformaldehyde) and measuring an absorption spectrum and an emission spectrum of the solution obtained. The absorption spectrum can be measured using a commercially available spectrophotometer, and the emission spectrum can be measured using a commercially available fluorometer.

Since the maximum wavelength of the absorption spectrum of the component (D) is in the range of 300 nm or more and 450 nm or less and, owing to this, the component has sufficient absorption for light (ultraviolet rays) emitted by a UV-LED light source (350 nm or more and 420 nm or less), the ultraviolet-curable resin composition can be sufficiently cured even when a UV-LED is used.

The ultraviolet-curable resin composition sufficiently cures in a shielding portion and a deep portion due to the use of the component (D). Although the details of this are unknown, it is presumed that since the component (D) has a maximum wavelength of the emission spectrum in a range of 350 nm or more and 500 nm or less, the component (C) can satisfactorily absorb light emitted from the component (D) described later, and therefore a polymerization initiating action (radical generation reaction) of the component (C) existing in a shielding portion and a deep portion is sufficiently exerted, and curing in the shielding portion and the deep portion sufficiently proceeds in the ultraviolet-curable resin composition.

Physical properties of the component (D) other than the maximum wavelength of the absorption spectrum and the maximum wavelength of the emission spectrum are not particularly limited.

The content of the component (D) in the ultraviolet-curable resin composition is not particularly limited. From the viewpoint of being superior in curability in a shielding portion and a deep portion, the content of the component (D) is preferably 0.00001 mass % or more (in a narrower sense, more than 0.00001 mass %) and 0.05 mass % or less (in a narrower sense, less than 0.05 mass %) based on 100 mass % of the ultraviolet-curable resin composition in terms of solid content. The upper limit value of the above-mentioned numerical range is preferably 0.03 mass % or less (in a narrower sense, less than 0.03 mass %) from the viewpoint of not impairing the reactivity of the photopolymerization initiator. The lower limit value of the above-mentioned numerical range is preferably 0.0001 mass % or more (in a narrower sense, more than 0.0001 mass %), and more preferably 0.001 mass % or more (in a narrower sense, more than 0.001 mass %) from the viewpoint of more reliably enhancing the curability. Therefore, more suitable numerical values can be obtained for the upper limit value and the lower limit value on the basis of mutually independent points of view. For example, when more suitable numerical values are assigned to both the upper limit value and the lower limit value, one suitable numerical value range for the content of the component (D) is 0.0001 mass % or more (in a narrower sense, more than 0.0001 mass %) and 0.03 mass % or less (in a narrower sense, less than 0.03 mass %). Further, when more preferable numerical values are assigned to both the upper limit value and the lower limit value, one suitable numerical value range is 0.001 mass % or more (in a narrower sense, more than 0.001 mass %) and 0.03 mass % or less (in a narrower sense, less than 0.03 mass %). Further, when numerical values more preferable than the above-described ranges are assigned to both the upper limit value and the lower limit value, one suitable numerical value range is 0.01 mass % or more (in a narrower sense, more than 0.01 mass %) and 0.03 mass % or less (in a narrower sense, less than 0.03 mass %).

### (Polymerization Inhibitor (E))

The ultraviolet-curable resin composition of the present embodiment may contain a polymerization inhibitor (E) (hereinafter, referred to as component (E)). The component (E) is not particularly limited, and various known polymerization inhibitors can be used. The component (E) may be used singly or two or more kinds thereof may be used in combination.

Typical examples of the component (E) include, but are not limited to, hydroquinone, trimethylhydroquinone, p-methoxyphenol, phenothiazine, aluminum N-nitrosophenylhydroxylamine, and 2,6-di-tert-butyl-4-methylphenol.

The typical examples of the component (E) are preferably at least one compound selected from the group consisting of aluminum N-nitrosophenylhydroxylamine and phenothiazine.

The content of the component (E) in the ultraviolet-curable resin composition is not particularly limited. From the viewpoint of not impairing the reactivity of the photopolymerization initiator, the content of the component (E) is preferably 0.0001 mass % or more (in a narrower sense, more than 0.0001 mass %) and 0.05 mass % or less (in a narrower sense, less than 0.05%) based on 100 mass % of the composition in terms of solid content.

### (Reactive Diluent)

The ultraviolet-curable resin composition of the present embodiment may contain a reactive diluent. The reactive diluent is a compound having an ultraviolet-reactive functional group other than the component (A), such as a carbon-carbon unsaturated bond. The reactive diluent may be used singly or two or more kinds thereof may be used in combination.

Typical examples of the reactive diluent include, but are not limited to, (meth)acrylic acid, mono(meth)acrylates, styrene, α-methylstyrene, and ethyl carbitol acrylate.

Typical examples of the mono(meth)acrylate include, but are not limited to, the hydroxy group-containing mono(meth)acrylates and the alkyl(meth)acrylates described above.

Typical examples of the alkyl (meth)acrylate include, but are not limited to, methyl (meth)acrylate, ethyl (meth)acrylate, propyl (meth)acrylate, butyl (meth)acrylate, pentyl (meth)acrylate, hexyl (meth)acrylate, heptyl (meth)acrylate, octyl (meth)acrylate, nonyl (meth)acrylate, decyl (meth)acrylate, undecyl (meth)acrylate, lauryl (meth)acrylate, tridecyl (meth)acrylate, myristyl (meth)acrylate, pentadecyl (meth)acrylate, palmityl (meth)acrylate, heptadecyl (meth)acrylate, stearyl (meth)acrylate, isopropyl (meth)acrylate, tert-butyl (meth)acrylate, isobutyl (meth)acrylate, isopentyl (meth)acrylate, methylbutyl (meth)acrylate, isododecyl (meth)acrylate, isotridecyl (meth)acrylate, isomyristyl (meth)acrylate, isopentadecyl (meth)acrylate, isohexadecyl (meth)acrylate, isoheptadecyl (meth)acrylate, isostearyl (meth)acrylate, nonadecyl (meth)acrylate, eicosyl (meth)acrylate, henicosyl (meth)acrylate, docosyl (meth)acrylate, tricosyl (meth)acrylate, tetracosyl (meth)acrylate, pentacosyl (meth)acrylate, hexacosyl (meth)acrylate, heptacosyl (meth)acrylate, and octacosyl (meth)acrylate.

When a reactive diluent is used in the ultraviolet-curable resin composition, the total content of the component (A) and the reactive diluent in the composition is preferably 25 mass % or more (in a narrower sense, more than 25 mass %) and 85 mass % or less (in a narrower sense, less than 85 mass %) based on 100 mass % of the composition in terms of solid content.

In the ultraviolet-curable resin composition, the content ratios of the component (A) and the reactive diluent are not particularly limited. From the viewpoint of adjusting the crosslinking density, when the total of the component (A) and the reactive diluent is assumed to be 100 mass %, the content ratio of the component (A) is preferably 20 mass % or more (in a narrower sense, more than 20 mass %) and 100mass % or less, and the content ratio of the reactive diluent is preferably 0 mass % or more and 80 mass % or less (in a narrower sense, less than 80 mass %). In addition, in consideration of hardness, scratch resistance, and so on of a cured product, it is preferable that the content ratio of the component (A) is 50 mass % or more (in a narrower sense, more than 50 mass %) and 95 mass % or less (in a narrower sense, less than 95 mass %), and the content ratio of the reactive diluent is 5 mass % or more (in a narrower sense, more than 5% by mass) and 50 mass % or less (in a narrower sense, less than 50 mass %).

### (Photopolymerization Initiator)

The ultraviolet-curable resin composition may contain a photopolymerization initiator other than the component (C) as necessary as long as the effect of the present invention is not impaired. Two or more such photopolymerization initiators may be used in combination. Typical examples of the photopolymerization initiator include, but are not limited to, 1-hydroxycyclohexyl phenyl ketone, 2,2-dimethoxy-1,2-diphenylethan-1-one, 1-[4-(2-hydroxyethoxy) phenyl]-2-hydroxy-2-methyl-1-propan-1-one, 2-hydroxy-2-methyl-1-phenylpropan-1-one, 2-hydroxy-1-{4-[4-(2-hydroxy-2-methylpropionyl)benzyl]phenyl}-2-methylpropan-1-one, 2-methyl-1-[4-(methylthio)phenyl]-2-morpholinopropan-1-one, 2-benzyl-2-dimethylamino-1-(4-morpholinophenyl)butan-1-one, 2-dimethylamino-2-(4-methylbenzyl)-1-(4-morpholin-4-ylphenyl) butan-1-one, 1-[4-(phenylthio)]-1,2-octanedione-2-(O-benzoyloxime), 1-[9-ethyl-6-(2-methylbenzoyl)-9H-carbazol-3-yl]ethanone-1-(O-acetyloxime), oxy-phenyl-acetic acid 2-[2-oxo-2-phenyl-acetoxy-ethoxy]-ethyl ester and oxy-phenyl-acetic acid 2-[2-hydroxy-ethoxy]-ethyl ester, benzophenone, 4-methylbenzophenone, 2,4,6-trimethylbenzophenone, and 4-phenylbenzophenone.

The content of the photopolymerization initiator other than the component (C) in the ultraviolet-curable resin composition is not particularly limited. The content of the photopolymerization initiator is preferably 0.5 parts by mass or more and 15 parts by mass or less based on 100 parts by mass of the composition in terms of solid content from the viewpoint of the progress of the reaction of(meth)acryloyl groups.

### (Solvent)

The ultraviolet-curable resin composition may contain a solvent in consideration of coating workability and so on. Typical examples of the solvent include, but are not limited to, methyl ethyl ketone, methyl isobutyl ketone, methyl acetate, ethyl acetate, butyl acetate, ethanol, n-propyl alcohol, isopropyl alcohol, n-butanol, isobutyl alcohol, tert-butyl alcohol, diacetone alcohol, acetylacetone, toluene, xylene, n-hexane, cyclohexane, methylcyclohexane, n-heptane, isopropyl ether, methyl cellosolve, ethyl cellosolve, 1,4-dioxane, propylene glycol monomethyl ether, ethylene glycol monoethyl ether acetate, and propylene glycol monomethyl ether acetate. The solvent may be used singly or two or more kinds thereof may be used in combination. In consideration of the surface smoothness of a cured film obtained from the composition, the solvent is preferably at least one selected from the group consisting of glycol ethers, alcohols, and ketones.

The content of the solvent in the ultraviolet-curable resin composition is not particularly limited. When a solvent is contained in the composition, the content of the solvent is preferably in a range in which the solid concentration of the composition is 1 mass % or more and 60 mass % or less from the viewpoint of coatability.

### (Additive)

The ultraviolet-curable resin composition may contain an agent that is not any of the solvent, the reactive diluent, and the photopolymerization initiator as an additive as necessary as long as the effect of the present invention is not impaired. The additive may be used singly or two or more kinds thereof may be used in combination. Typical examples of the additive include, but are not limited to, an antistatic agent, an antioxidant, an ultraviolet absorber, a light stabilizer, an antifoaming agent, a surface conditioner, an antifogging agent, a hydrophilizing agent, an antifouling agent, a pigment, a metal oxide fine particle dispersion, and an organic fine particle dispersion.

The content of the additive in the ultraviolet-curable resin composition is not particularly limited. The content of the additive is preferably 0.05 parts by mass or more and 1 part by mass or less based on 100 parts by mass of the composition in terms of solid content.

### Adhesive

The adhesive of the present embodiment comprises the ultraviolet-curable resin composition described above. The adhesive of the present embodiment may contain a solvent and an additive as necessary as long as the effect of the present invention is not impaired. The solvent and the additive each may be used singly or two or more kinds thereof may be used in combination.

The solvent is not particularly limited. Typical examples of the solvent include, but are not limited to, aromatic hydrocarbons such as benzene, toluene, ethylbenzene, n-propylbenzene, t-butylbenzene, o-xylene, m-xylene, p-xylene, tetralin, decalin, and aromatic naphtha; aliphatic hydrocarbons such as n-hexane, n-heptane, n-octane, isooctane, and n-decane; cycloaliphatic hydrocarbons such as cyclohexane; esters such as ethyl acetate, n-butyl acetate, n-amyl acetate, 2-hydroxyethyl acetate, 2-butoxyethyl acetate, 3-methoxybutyl acetate, and methyl benzoate; ketones such as acetone, methyl ethyl ketone, methyl isobutyl ketone, isophorone, cyclohexanone, and methylcyclohexanone; glycol ethers such as ethylene glycol monomethyl ether, ethylene glycol monoethyl ether, ethylene glycol monobutyl ether, diethylene glycol monomethyl ether, diethylene glycol monoethyl ether and diethylene glycol monobutyl ether; alcohols such as methyl alcohol, ethyl alcohol, n-propyl alcohol, isopropyl alcohol, n-butyl alcohol, isobutyl alcohol, s-butyl alcohol, and t-butyl alcohol.

The additive is not particularly limited. Typical examples of the additive include, but are not limited to, a tackifier, a plasticizer, an antioxidant, a surface conditioner, a surfactant, an ultraviolet absorber, an antioxidant, a light stabilizer, an inorganic filler, a silane coupling agent, colloidal silica, an antifoaming agent, a wetting agent, a rust inhibitor, a crystal nucleating agent, and a crystallization accelerator.

The content of the additive in the adhesive is not particularly limited. From the viewpoint of adjustment of curability or adjustment of curing inhibition, the content of the additive is preferably 0.05 parts by mass or more and 1 part by mass or less based on 100 parts by mass of the adhesive in terms of solid content.

The adhesive of the present embodiment is superior in curability in a light shielding portion and a deep portion, and thus is suitable as an adhesive to be used for a shadow portion and a narrow portion, for example, an adhesive to be used between a protective panel and a touch panel of an image display device or the like, or an adhesive to be used for bonding various electronic components in an electronic circuit board.

### Sealant

The sealant of the present embodiment comprises the ultraviolet-curable resin composition described above. The sealant of the present embodiment may contain an additive as necessary as long as the effect of the present invention is not impaired. The additive may be used singly or two or more kinds thereof may be used in combination.

The sealant is not particularly limited. Typical examples of the sealant include, but are not limited to, an ion scavenger, a silane coupling agent, a fluorine coupling agent, a leveling agent, an antifoaming agent, an antioxidant, a surface lubricant, a wet dispersant, a stress releaser, a flame retardant, a colorant (such as carbon black), and a diluent.

The content of the additive in the sealant is not particularly limited. From the viewpoint of adjustment of curability or adjustment of curing inhibition, the content of the additive is preferably 0.1 parts by mass or more and 5 parts by mass or less based on 100 parts by mass of the sealant in terms of solid content.

Since the sealant of the present embodiment is superior in curability in a light shielding portion and a deep portion, the sealant can be applied to a sealant to be used for a component having a complicated shape and hardly irradiated with ultraviolet rays, or a sealant having a shielding portion in a use environment. For example, the sealant of the present embodiment is suitable as a sealant to be used for an optical lens unit, a sealant for an electronic component with a lead, and an underfill agent.

### Insulating Protective Agent

The insulating protective agent of the present embodiment comprises the ultraviolet-curable resin composition described above. The insulating protective agent of the present embodiment can also be used as an insulating protective agent for an electronic circuit board. The insulating protective agent of the present embodiment is applied to an electronic circuit board and cured to form a cured film (cured product) having an insulating property and moisture resistance, and can protect the electronic circuit board from the external environment.

The insulating protective agent of the present embodiment may contain a diluent and an additive as necessary as long as the effect of the present invention is not impaired. The diluent and the additive each may be used singly or two or more kinds thereof may be used in combination.

Typical examples of the diluent include, but are not limited to, dimethyl carbonate, diethyl carbonate, ethylene carbonate, propylene carbonate, ethyl acetate, γ-butyl lactone (γ-butyrolactone), acetone, methyl isobutyl ketone, ethyl methyl ketone, cyclohexanone, diisopropyl ether, ethylene glycol monoethyl ether, propylene glycol monomethyl ether, dioxane, tetrahydrofuran, methanol, ethanol, n-propanol, benzene, toluene, xylene, dimethyl sulfoxide, and phenyl glycidyl ether.

The additive is not particularly limited. Typical examples of the additive include, but are not limited to, a surfactant, an adhesion improver, an antifoaming agent, a sensitizer, and a fluorescent agent other than the component (D).

The content of the additive in the insulating protective agent is not particularly limited. The content of the additive is preferably 0.05 parts by mass or more and 100 parts by mass or less based on 100 parts by mass of the insulating protective agent in terms of solid content.

Since the insulating protective agent of the present embodiment is superior in curability in a light shielding portion and a deep portion, the insulating protective agent can be a suitable insulating protective agent in an electronic circuit board on which an electronic component is mounted and in which a shadow portion or a narrow portion exists.

### Electronic Circuit Board

The electronic circuit board of the present embodiment comprises a cured product of the insulating protective agent described above. A typical example of the cured product is one obtained by applying the insulating protective agent to an electronic circuit board and applying ultraviolet rays. Typical examples of the electronic circuit board include, but are not limited to, a rigid printed circuit board and a flexible printed circuit board.

Typical examples of an ultraviolet light source to be used for a curing reaction include, but are not limited to, a xenon lamp, a high-pressure mercury lamp, a metal halide lamp, and an LED lamp. As the ultraviolet light source, an LED lamp is preferable from the viewpoint of energy saving and space saving. The light quantity, the light source arrangement, the conveyance speed, and so on may be adjusted, as necessary.

Typical examples of the coating method include, but are not limited to, bar coater coating, Meyer bar coating, air knife coating, dispenser coating, spray coating, gravure printing, reverse gravure printing, offset printing, flexographic printing, screen printing, jet printing, dip coating, and curtain coating.

### EXAMPLES

Hereinafter, the above-described embodiments will be described more specifically by way of examples. However, the present invention and the embodiments are not limited to these examples. In Examples, “%” and “parts” mean “mass %” and “parts by mass”, respectively, unless otherwise specified.

### Preparation of Ultraviolet-Curable Resin Composition

### Example 1

An ultraviolet-curable resin composition having a solid content of 50% was prepared by blending 100 parts of trimethylolpropane triacrylate (trade name “Viscoat #295” manufactured by Osaka Organic Chemical Industry Ltd.) (hereinafter, referred to as component (A1)) as the component (A), 137 parts of pentaerythritol tetrakis (3-mercaptobutyrate) (trade name “KarenzMT (registered trademark) PE1” manufactured by Showa Denko K.K.) (hereinafter referred to as component (B1)) as the component (B), 0.2 parts of bis(2,4,6-trimethylbenzoyl) phenylphosphine oxide (trade name “Omnirad 819” manufactured by IGM Resins B.V.) (hereinafter referred to as component (C1)) as the component (C), 0.002 parts of 2,5-thiophenediyl (5-tert-butyl-1,3-benzoxazole) (trade name “Tinopal OB” manufactured by BASF Japan Ltd.) (hereinafter referred to as component (D1)) as the component (D), and 0.005 parts of aluminum N-nitrosophenylhydroxylamine (trade name “Q-1301” manufactured by FUJIFILM Wako Pure Chemical Corporation) as a polymerization inhibitor in solid content ratios, and diluting the blend with methyl ethyl ketone.

### Examples 2 to 21 and Comparative Examples 1 to 8

Ultraviolet-curable resin compositions were manufactured by the same procedure as in Example 1 except that the compositions and blending amounts of the components (A) to (D) in Example 1 were changed to those shown in Tables 1 to 3.

### (Absorbance of Photopolymerization Initiator (C) at 385 nm)

The component (C1) and acetonitrile were mixed and a solution in acetonitrile with a concentration of 500 ppm was thereby prepared, and the absorbance at 385 nm was measured with a spectrophotometer (manufactured by Shimadzu Corporation, device name “ultraviolet-visible spectrophotometer UV-2600”) using a two-face translucent quartz cell (rectangular cell manufactured by Shimadzu GLC Ltd.) having an optical path length of 10 mm. The component (C2) and the components (c1) to (c2) were also measured in the same manner.

TABLE 1

| | | Example 1 | Example 2 | Example 3 | Example 4 | Example 5 | Example 6 |
|---|---|---|---|---|---|---|---|
| (A) | (A1) | 100 | 100 | 100 | 100 | 100 | 100 |
| (B) | (B1) | 137 | | 137 | 137 | 69 | 34 |
| | (B2) | | 191 | | | | |
| (C) | (C1) | 0.2 | 0.2 | | 0.2 | 0.2 | 0.2 |
| | (C2) | | | 0.2 | | | |
| (D) | (D1) | 0.002 | 0.002 | 0.002 | | 0.002 | 0.002 |
| | (D2) | | | | 0.002 | | |

| | | | | | | |
|---|---|---|---|---|---|---|
| Content (%) of component (B) | 57.8 | 65.6 | 57.8 | 57.8 | 40.8 | 25.3 |
| Content (%) of component (D) | 0.00084 | 0.00069 | 0.00084 | 0.00084 | 0.0012 | 0.0015 |
| Shadow portion curing (mm) | 12.5 | 16.0 | 6.5 | 12.0 | 13.5 | 8.5 |

| | | Example 7 | Example 8 | Example 9 | Example 10 | Example 11 | Example 12 |
|---|---|---|---|---|---|---|---|
| (A) | (A1) | 100 | 100 | 100 | 100 | 100 | 100 |
| (B) | (B1) | 17 | 137 | 137 | 137 | 137 | 137 |
| | (B2) | | | | | | |
| (C) | (C1) | 0.2 | 0.2 | 0.2 | 0.2 | 0.2 | 0.2 |
| | (C2) | | | | | | |
| (D) | (D1) | 0.002 | 0.020 | 0.001 | 0.050 | 0.0001 | 0.002 |
| | (D2) | | | | | | |

| | | | | | | |
|---|---|---|---|---|---|---|
| Content (%) of component (B) | 14.5 | 57.8 | 57.8 | 57.8 | 57.8 | 57.8 |
| Content (%) of component (D) | 0.0017 | 0.0084 | 0.00042 | 0.021 | 0.000042 | 0.00084 |
| Shadow portion curing (mm) | 6.5 | 13.0 | 12.0 | 32.0 | 9.5 | 39.0 |

TABLE 2

| | | Example 13 | Example 14 | Example 15 | Example 16 | Example 17 |
|---|---|---|---|---|---|---|
| (A) | (A1) | | | | | |
| | (A2) | 100 | | | | |
| | (A3) | | 100 | | | |
| | (A4) | | | 100 | | |
| | (A5) | | | | 100 | |
| | (A6) | | | | | 100 |
| | (A7) | | | | | |
| | (A8) | | | | | |
| | (A9) | | | | | |
| (B) | (B1) | 56 | 87 | 88 | 142 | 17 |
| (C) | (C1) | 0.2 | 0.2 | 0.2 | 0.2 | 0.2 |
| (D) | (D1) | 0.002 | 0.002 | 0.002 | 0.002 | 0.002 |
| (D) | (D3) | | | | | |

| | | | | | |
|---|---|---|---|---|---|
| Content (%) of component (B) | 35.8 | 46.5 | 46.8 | 58.6 | 14.5 |
| Content (%) of component (D) | 0.0013 | 0.0011 | 0.0011 | 0.00083 | 0.0017 |
| Shadow portion curing (mm) | 7.0 | 8.5 | 11.5 | 17.0 | 8.5 |

| | | Example 18 | Example 19 | Example 20 | Example 21 |
|---|---|---|---|---|---|
| (A) | (A1) | | | | 100 |
| | (A2) | | | | |
| | (A3) | | | | |
| | (A4) | | | | |
| | (A5) | | | | |
| | (A6) | | | | |
| | (A7) | 100 | | | |
| | (A8) | | 100 | | |
| | (A9) | | | 100 | |
| (B) | (B1) | 19 | 96 | 137 | 137 |
| (C) | (C1) | 0.2 | 0.2 | 0.2 | 0.2 |
| (D) | (D1) | 0.002 | 0.002 | 0.002 | |
| (D) | (D3) | | | | 0.002 |

| | | | | |
|---|---|---|---|---|
| Content (%) of component (B) | 15.9 | 48.9 | 57.8 | 57.8 |
| Content (%) of component (D) | 0.0017 | 0.001 | 0.00084 | 0.00084 |
| Shadow portion curing (mm) | 9.0 | 10.5 | 7.0 | 11.0 |

TABLE 3

| | | Comparative | Comparative | Comparative | Comparative |
|---|---|---|---|---|---|
| | | Example 1 | Example 2 | Example 3 | Example 4 |
| (A) | (A1) | 100 | 100 | 100 | 100 |
| | (A9) | | | | |
| (B) | (B1) | | 137 | | 137 |
| | (B2) | | | | |
| (C) | (C1) | 0.2 | 0.2 | 0.2 | |
| | (C2) | | | | |
| (D) | (D1) | | | 0.002 | 0.002 |
| | (D2) | | | | |
| | (b1) | | | 123.00 | |
| | (c1) | | | | 0.20 |
| | (c2) | | | | |
| Content (%) of | | 0 | 57.8 | 55.1 | 57.8 |
| component (B) | | | | | |
| Content (%) of | | 0 | 0 | 0.0009 | 0.00084 |
| component (D) | | | | | |
| Shadow portion | | 4.0 | 5.5 | 5.5 | 2.5 |
| curing (mm) | | | | | |
| | | Comparative | Comparative | Comparative | Comparative |
| | | Example 5 | Example 6 | Example 7 | Example 8 |
| (A) | (A1) | 100 | 100 | | |
| | (A9) | | | 100 | 100 |
| (B) | (B1) | 137 | 9 | | 137 |
| | (B2) | | | | |
| (C) | (C1) | | 0.2 | 0.2 | 0.2 |
| | (C2) | | | | |
| (D) | (D1) | 0.002 | 0.002 | | |
| | (D2) | | | | |
| | (b1) | | | | |
| | (c1) | | | | |
| | (c2) | 0.20 | | | |

| | | | | |
|---|---|---|---|---|
| Content (%) of | 57.8 | 8.2 | 0 | 57.8 |
| component (B) | | | | |
| Content (%) of | 0.00084 | 0.0018 | 0 | 0 |
| component (D) | | | | |
| Shadow portion | 5.0 | 5.5 | 0.0 | 3.0 |
| curing (mm) | | | | |

The blending amounts in Tables 1 to 3 are values of parts by mass in terms of solid content. Abbreviations in Tables 1 to 3 are as follows. The maximum wavelength of the absorption spectrum and the maximum wavelength of the emission spectrum of the components (D1) to (D2) are values disclosed in the catalog of each manufacturer. A blank cell in each table means that the component corresponding to the blank cell is not contained.
(A1): Trimethylolpropane triacrylate (trade name “Viscoat #295” manufactured by Osaka Organic Chemical Industry Ltd.)
(A2): Bisphenol F EO-modified (n=2) diacrylate (trade name “ARONIX M-208” manufactured by Toagosei Co., Ltd.)
(A3): Tricyclodecane dimethanol diacrylate (trade name “A-DCP” manufactured by Shin-Nakamura Chemical Co., Ltd.)
(A4): Isocyanurate EO-modified di-and triacrylates (trade name “ARONIX M-313” manufactured by Toagosei Co., Ltd.)
(A5): Mixture of dipentaerythritol pentaacrylate and dipentaerythritol hexaacrylate (trade name “NK Ester A-9550W” manufactured by Shin-Nakamura Chemical Co., Ltd.)
(A6): Urethane acrylate (trade name “UA-160TM” manufactured by Shin-Nakamura Chemical Co., Ltd., number of(meth)acryloyl groups in the molecule: 2)
(A7): Urethane acrylate (trade name “UA-7100” manufactured by Shin-Nakamura Chemical Co., Ltd., number of(meth)acryloyl groups in the molecule: 3)
(A8): Urethane acrylate (trade name “UA-6LPA” manufactured by Shin-Nakamura Chemical Co., Ltd., number of(meth)acryloyl groups in the molecule: 6)
(A9): 1,4-Cyclohexanedimethanol divinyl ether (trade name “CHDVE” manufactured by Nippon Carbide Industries Co., Inc.)
(B1): Pentaerythritol tetrakis (3-mercaptobutyrate) (trade name “KarenzMT (registered trademark) PE1” manufactured by Showa Denko K.K.)
(B2): 1,3,5-Tris(3-mercaptobutyryloxyethyl)-1,3,5-triazine-2,4,6(1H,3H,5H)-trione (trade name “KarenzMT (registered trademark) NR₁” manufactured by Showa Denko K.K.)
(b1): Pentaerythritol tetrakis(3-mercaptopropionate) (trade name “PEMP” manufactured by SC Organic Chemical Co., Ltd.)
(C1): Bis(2,4,6-trimethylbenzoyl)-phenylphosphine oxide (trade name “Omnirad 819” manufactured by IGM Resins B.V, absorbance: 0.91 at 385 nm)
(C2): 2,4,6-Trimethylbenzoyldiphenylphosphine oxide (trade name “Omnirad TPO H” manufactured by IGM Resins B.V, absorbance: 0.76 at 385 nm)
(c1): 2-Methyl-1-[4-methylthio]phenyl]-2-morpholinopropan-1-one (trade name “Omnirad 907” manufactured by IGM Resins B.V, absorbance: 0.065 at 385 nm)
(c2): 2-Benzyl-2-dimethylamino-1-(4-morpholinophenyl) butan-1-one (trade name “Omnirad 369” manufactured by IGM Resins B.V, absorbance: 0.39 at 385 nm)
(D1): 2,5-Thiophenediyl(5-tert-butyl-1,3-benzoxazole) (trade name “Tinopal OB” manufactured by BASF Japan Ltd., maximum wavelength of absorption spectrum: 375 nm, maximum wavelength of emission spectrum: 435 nm)
(D2): Pyrene (trade name “special grade pyrene” manufactured by FUJIFILM Wako Pure Chemical Corporation, maximum wavelength of absorption spectrum: 340 nm, maximum wavelength of emission spectrum: 378 nm, 398 nm, 420 nm)

### (Shadow Part Curability)

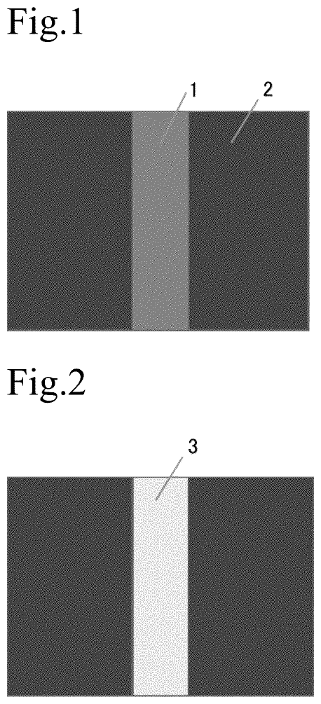

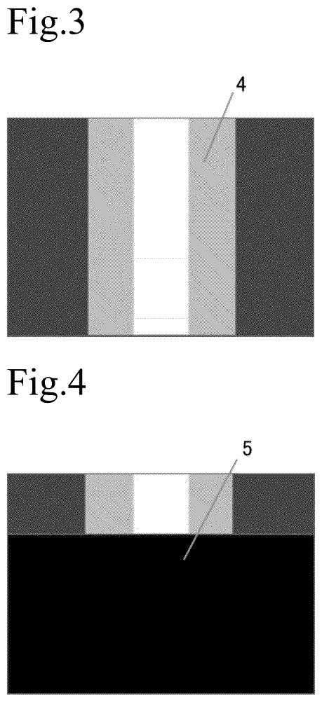

A spacer was disposed on an FRP substrate (trade name “FRP” manufactured by Nippon Testpanel Co., Ltd.) having a width of 150 mm×a length of 70 mm×a thickness of 2 mm (FIG. 1), and the ultraviolet-curable resin composition of Examples 1 to 11, Examples 13 to 21, and Comparative Examples 1 to 8 was applied to a portion not covered with the spacer using a cylindrical glass rod, and a film was formed thereby to have a width of 25 mm×a length of 70 mm×a film thickness of 400 μm (FIG. 2). Next, a PET film having a release layer and having a width of 70 mm×a length of 100 mm×a thickness of 75 μm was bonded to the ultraviolet-curable resin composition with the release layer facing the composition such that air did not remain (FIG. 3). Then, in a state where a light shielding plate having a width of 150 mm×a length of 50 mm×a thickness of 2 mm was placed on the PET film (FIG. 4), ultraviolet rays were applied from the light shielding plate side with an integrated light quantity of 10,000 mJ/cm² using an ultraviolet irradiation device (belt conveyor type UV-LED irradiation device, UV-LED irradiation wavelength: 385 nm, manufactured by GS Yuasa

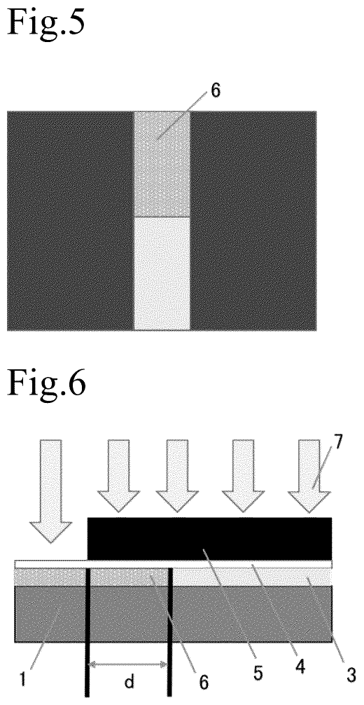

Corporation). Thereafter, the light shielding plate and the PET film were peeled off from the ends and a boundary line between a portion where the ultraviolet-curable resin composition had become a cured product and an uncured state portion was confirmed (FIG. 5), and the distance (d in FIG. 6) from the end (reference line) of the light shielding plate to the boundary line was measured and defined as “shadow part curability (mm)”. These measurements were performed three times, and the average value thereof was calculated. The results are shown in Tables 1 to 4.

For the shadow part curability in the ultraviolet-curable resin composition of Example 12, the shadow part curability was evaluated in the same manner as the evaluation method described above except that ultraviolet rays with an integrated light quantity of 10,000 mJ/cm² were applied using an ultraviolet irradiation device (belt conveyor type UV irradiation device 120 W/cm high-pressure mercury lamp manufactured by Multiply Corporation) in the evaluation method described above. The results are shown in Table 1.

Since the ultraviolet-curable resin compositions of Examples 1 to 21 have a long shadow portion curing distance, the compositions have sufficient curability even in a shielding portion and a deep portion where ultraviolet rays do not reach. On the other hand, the ultraviolet-curable resin compositions of Comparative Examples 1 to 8 have a short shadow portion curing distance, and thus have insufficient curability in a shielding portion and a deep portion where ultraviolet rays do not reach, or are in a state where curability cannot be confirmed. The ultraviolet-curable resin composition of Example 12 has been found to be further better in the curability of a shielding portion and a deep portion from the fact that the distance of shadow portion curing has rendered extremely long by using a high-pressure mercury lamp having higher energy than an LED lamp as an ultraviolet light source.

In addition, in the evaluation of the shadow part curability, a non-transparent FRP substrate was used as a substrate. This is because when a transparent substrate such as glass sheet is used, ultraviolet rays travel inside the substrate to reach the resin composition of the shadow portion, and thus there is a problem that the shadow part curability cannot be evaluated correctly. In the case of a non-transparent FRP substrate, ultraviolet rays hardly travel inside the substrate, and as a result, the shadow part curability can be correctly evaluated.

As described above, the above embodiments and examples have been disclosed not for limiting the present invention but for describing these embodiments and examples. Furthermore, modification examples made within the scope of the present invention, inclusive of other combinations disclosed in the above embodiments, will also be included in the scope of the patent claims.

### INDUSTRIAL APPLICABILITY

The ultraviolet-curable resin composition of the present invention can be widely utilized in the electric or electronic device field or the optical field through the utilization, for example, as an adhesive, as a sealant, or as an insulating protective agent, or as an electronic circuit board or the like containing a cured product of the insulating protective agent.

### DESCRIPTION OF REFERENCE SIGNS

1: FRP substrate (non-transparent member)
2: Spacer
3: Ultraviolet-curable resin composition (uncured)
4: PET film
5: Light shielding plate (non-transparent member)
6: Ultraviolet-curable resin composition (cured)
7: Irradiation with ultraviolet rays
d: Distance from end (reference line) of light shielding plate to cured/uncured boundary line of ultraviolet-curable resin composition (shadow portion curing distance of ultraviolet-curable resin composition)

1. An ultraviolet-curable resin composition comprising:
(A) at least one polymer selected from the group consisting of poly(meth)acrylates (al) and polyvinyl ethers (a2);
(B) a compound having at least two secondary thiol groups in a molecule thereof;
(C) a photopolymerization initiator a solution of which in acetonitrile with a concentration of 500 ppm has an absorbance of 0.50 or more in an optical path length of 10 mm at 385 nm; and
(D) an organic compound that emits light upon absorbing ultraviolet rays, having a maximum wavelength of an absorption spectrum in a range of 300 nm or more and 450 nm or less, and having a maximum wavelength of an emission spectrum in a range of 350 nm or more and 500 nm or less;
wherein a content of the compound (B) is 10 mass % or more and 70 mass % or less based on 100 mass % of the resin composition in terms of solid content.

2. The ultraviolet-curable resin composition according to claim 1,
wherein the component (B) is a compound having at least three secondary thiol groups in a molecule thereof.

3. The ultraviolet-curable resin composition according to claim 1 or 2,
wherein a content of the component (D) is 0.00001 mass % or more and 0.05 mass % or less based on 100 mass % of the resin composition in terms of solid content.

4. The ultraviolet-curable resin composition according to any one of claims 1 to 3,
wherein the component (D) is at least one compound selected from the group consisting of benzoxazole compounds, naphthalene compounds, anthracene compounds, pyrene compounds, stilbene compounds, and coumarin compounds.

5. The ultraviolet-curable resin composition according to any one of claims 1 to 4,
wherein the component (C) is an acylphosphine oxide compound.

6. The ultraviolet-curable resin composition according to any one of claims 1 to 5, further comprising a polymerization inhibitor (E).

7. The ultraviolet-curable resin composition according to claim 6,
wherein the component (E) is at least one compound selected from the group consisting of aluminum N-nitrosophenylhydroxylamine and phenothiazine.

8. An adhesive comprising the ultraviolet-curable resin composition according to any one of claims 1 to 7.

9. A sealant comprising the ultraviolet-curable resin composition according to any one of claims 1 to 7.

10. An insulating protective agent comprising the ultraviolet-curable resin composition according to any one of claims 1 to 7.

11. An electronic circuit board comprising a cured product of the insulating protective agent according to claim 10.
